(19) United States
(12) Patent Application Publication
(10) Pub. No.: US 2026/0172003 A1
(43) Pub. Date: Jun. 18, 2026

(54) ACOUSTIC WAVE DEVICE, ACOUSTIC WAVE FILTER, AND MULTIPLEXER

(71) Applicant: Murata Manufacturing Co., Ltd., Nagaokakyo-shi (JP)

(72) Inventor: Shinji BABA, Nagaokakyo-shi (JP)

(21) Appl. No.: 19/406,193

(22) Filed: Dec. 2, 2025

(30) Foreign Application Priority Data
Dec. 18, 2024 (JP) 2024-221811

(51) Int. Cl. H03H 9/56; H03H 9/13; H03H 9/70

(52) U.S. Cl. CPC H03H 9/568; H03H 9/13; H03H 9/703

(57) ABSTRACT

An acoustic wave filter includes a mounting board including a first main surface, a piezoelectric substrate including a second main surface facing the first main surface with a gap interposed therebetween, a series-arm resonator including an IDT electrode and located on the piezoelectric substrate, a capacitor on the second main surface and connected in parallel with the series-arm resonator, and a floating planar electrode on the first main surface. An area surrounded by the IDT electrode, the capacitor, and traces, overlaps with at least a portion of the floating planar electrode in plan view of the first main surface and the second main surface.

### CROSS REFERENCE TO RELATED APPLICATIONS

This application claims the benefit of priority to Japanese Patent Application No. 2024-221811 filed on Dec. 18, 2024. The entire contents of this application are hereby incorporated herein by reference.

### BACKGROUND OF THE INVENTION

### 1. Field of the Invention

The present invention relates to acoustic wave devices, acoustic wave filters, and multiplexers.

### 2. Description of the Related Art

Japanese Unexamined Patent Application Publication No. 2013-243570 discloses an acoustic wave device including a series-arm resonator device disposed in a series-arm path connecting two signal terminals, a parallel-arm resonator device connected between the series-arm path and a first reference electrode, and a capacitance element connected between the series-arm path and a second reference electrode. According to Japanese Unexamined Patent Application Publication No. 2013-243570, an acoustic wave device with low insertion loss and having high attenuation in a radio-frequency range can be provided with the above configuration.

However, in the acoustic wave device described in Japanese Unexamined Patent Application Publication No. 2013-243570, attenuation characteristics of the acoustic wave device may be degraded due to a current loop formed by the parallel-arm resonator device, the first reference electrode, the second reference electrode, and the capacitance element.

### SUMMARY OF THE INVENTION

Example embodiments of the present invention provide acoustic wave devices, acoustic wave filters, and multiplexers each with improved attenuation characteristics.

An acoustic wave device according to an example embodiment of the present invention includes a first substrate including a first main surface, a second substrate including a second main surface facing the first main surface with a gap interposed therebetween, an acoustic wave resonator including a functional electrode and located in or on the second substrate, a bridging capacitance element on the second main surface and connected in parallel with the acoustic wave resonator, and a floating electrode on the first main surface. An area surrounded by the functional electrode, the bridging capacitance element, and a trace connecting the functional electrode and the bridging capacitance element, overlaps with at least a portion of the floating electrode in plan view of the first main surface and the second main surface.

An acoustic wave filter according to another example embodiment of the present invention includes a first substrate including a first main surface, a second substrate including a second main surface facing the first main surface with a gap interposed therebetween, a series-arm resonator in a series-arm path connecting a first input/output terminal and a second input/output terminal, a parallel-arm resonator connected between the series-arm path and ground, a bridging capacitance element on the second main surface and connected in parallel with one of the series-arm resonator and the parallel-arm resonator, and a floating electrode on the first main surface. The one of the series-arm resonator and the parallel-arm resonator is defined by an acoustic wave resonator including a functional electrode, and an area surrounded by the functional electrode, the bridging capacitance element, and a trace connecting the functional electrode and the bridging capacitance element, overlaps with at least a portion of the floating electrode in plan view of the first main surface and the second main surface.

A multiplexer according to an example embodiment of the present invention includes a common terminal, an acoustic wave filter according to an example embodiment of the present invention and connected to the common terminal, and a first filter connected to the common terminal.

According to example embodiments of the present invention, acoustic wave devices, acoustic wave filters, and multiplexers each with improved attenuation characteristics are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of an acoustic wave filter according to an example embodiment of the present invention.

FIG. 2A includes a plan view and a cross-sectional view schematically illustrating a first example of an acoustic wave resonator included in an acoustic wave filter according to an example embodiment of the present invention.

FIG. 2B is a cross-sectional view schematically illustrating a second example of an acoustic wave resonator included in an acoustic wave filter according to an example embodiment of the present invention.

FIG. 2C is a cross-sectional view schematically illustrating a third example of an acoustic wave resonator included in an acoustic wave filter according to an example embodiment of the present invention.

FIG. 2D is a cross-sectional view schematically illustrating a fourth example of an acoustic wave resonator included in an acoustic wave filter according to an example embodiment of the present invention.

FIG. 3A is a cross-sectional view of an acoustic wave filter according to an example embodiment of the present invention.

FIG. 3B is a cross-sectional view of an acoustic wave filter according to a comparative example.

FIG. 4 is a diagram illustrating an electrode layout of a series-arm resonator and a bridging capacitance element of an acoustic wave filter according to an example embodiment of the present invention.

FIG. 5 is a circuit diagram of a multiplexer according to an example embodiment of the present invention.

FIG. 6 is a cross-sectional view of a multiplexer according to an example embodiment of the present invention.

FIG. 7A is a first plan view illustrating an electrode layout of a multiplexer according to an example embodiment of the present invention.

FIG. 7B is a second plan view illustrating an electrode layout of a multiplexer according to an example embodiment of the present invention.

FIG. 7C is a third plan view illustrating an electrode layout of a multiplexer according to an example embodiment of the present invention.

FIG. 8A is a graph illustrating bandpass characteristics of acoustic wave filters included in multiplexers according to an example embodiment of the present invention, a first comparative example, and a second comparative example.

FIG. 8B is a graph illustrating a voltage standing wave ratio (VSWR) of acoustic wave filters included in multiplexers according to an example embodiment of the present invention, the first comparative example, and the second comparative example.

FIG. 8C is a graph illustrating isolation characteristics of multiplexers according to an example embodiment of the present invention, the first comparative example, and the second comparative example.

### DETAILED DESCRIPTION OF THE EXAMPLE EMBODIMENTS

Hereinafter, example embodiments of the present invention will be described in detail with reference to the drawings. Example embodiments described below all indicate comprehensive or specific examples. Various parameters, such as numerical values, shapes, materials, components, and arrangements and connection configurations of the components, which are illustrated in the following example embodiments are merely examples and are not intended to limit the present invention.

Each figure is a schematic diagram in which emphasis, omission, or adjustment of proportions has been appropriately made to illustrate example embodiments of the present invention, is not necessarily an exact illustration, and does not always represent actual shapes, positional relationships, and proportions. In each figure, components that are the same or substantially the same are denoted by the same symbols, and duplicated descriptions may be omitted or simplified.

In circuit configurations described in the present disclosure, “connected between A and B” means that something between A and B is connected to both A and B. The phrase also indicates a case where something is indirectly connected to A and B.

When a component is disposed in the present disclosure, “component A is disposed in series with path B” means that both the signal input end and the signal output end of component A are connected to somewhere in path B. Path B includes traces, wiring, electrodes, and terminals.

Terms indicating a relationship between elements, such as “parallel” and “perpendicular”, terms indicating the shape of an element, such as “rectangle”, and a numerical range do not only represent what those terms literally mean, but also include substantially equivalent ranges, for example, with an error of a few percent.

In the present disclosure, a “terminal” indicates a point at which a conductor within an element terminates. When the impedance of a conductor between elements is sufficiently low, a terminal is interpreted not only as a single point but also as any point on the conductor between the elements or the entire conductor.

In the present disclosure, the pass band of a filter is a portion of a frequency spectrum transmitted by the filter and is defined as the frequency range between two frequencies at which the power insertion loss is about 3 dB above the minimum value.

A resonant frequency and an anti-resonant frequency illustrated in the example embodiments and modifications are derived, for example, by setting an RF probe in contact with two input/output electrodes of an acoustic wave resonator or a capacitance element while the acoustic wave resonator or the capacitance element is not connected to other circuit elements, and measuring reflection characteristics (impedance characteristics) using an apparatus such as a network analyzer, for example.

A phrase “two resonant frequencies being different” or “two anti-resonant frequencies being different” is defined as the difference between the two resonant frequencies (or the two anti-resonant frequencies) that have been measured being, for example, about 0.1% or more of the measured frequencies. The above difference includes the error generated by a measuring device. A phrase “one resonant frequency being larger than one anti-resonant frequency” or “one resonant frequency being smaller than one anti-resonant frequency” is defined as the one resonant frequency that has been measured being larger (smaller) than the one anti-resonant frequency that has been measured by, for example, about 0.1% or more. The difference between the one resonant frequency that has been measured and the one anti-resonant frequency that has been measured includes the error generated by a measuring device.

In the present disclosure, a “band” means at least one of uplink and downlink operating bands of frequency bands predefined, for example, by a standardization organization (such as 3GPP (registered trademark) or Institute of Electrical and Electronics Engineers (IEEE)) for a communication system built using the radio access technology (RAT). Examples of the communication system used in the example embodiments include, but are not limited to, for example, a long term evolution (LTE) system, a 5th generation (5G)—new radio (NR) system, and a wireless local area network (WLAN) system. An uplink operating band of a frequency band refers to a frequency range designated for uplink use within the frequency band. A downlink operating band of a frequency band refers to a frequency range designated for downlink use within the frequency band.

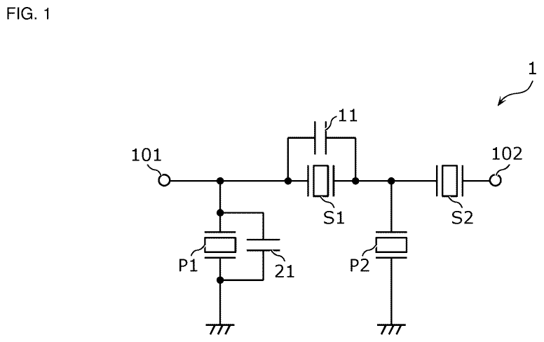

FIG. 1 is a circuit diagram of an acoustic wave filter 1 according to an example embodiment of the present invention. As illustrated in FIG. 1, the acoustic wave filter 1 is an example of an acoustic wave device and includes series-arm resonators S1 and S2, parallel-arm resonators P1 and P2, capacitors 11 and 21, and input/output terminals 101 and 102.

The series-arm resonators S1 and S2 each include an acoustic wave resonator and are disposed in series in a series-arm path connecting the input/output terminal 101 (first input/output terminal) and the input/output terminal 102 (second input/output terminal).

The parallel-arm resonators P1 and P2 each include an acoustic wave resonator and are connected between the series-arm path and ground. The parallel-arm resonator P1 is connected between the ground and a connection point between the input/output terminal 101 and the series-arm resonator S1. The parallel-arm resonator P2 is connected between the ground and a connection point between the series-arm resonators S1 and S2.

The capacitor 11 is an example of a bridging capacitance element and is connected in parallel with the series-arm resonator S1. The capacitor 21 is an example of a bridging capacitance element and is connected in parallel with the parallel-arm resonator P1.

The series-arm resonators S1 and S2 and the parallel-arm resonators P1 and P2 each have a resonant frequency at which the impedance is minimum and an anti-resonant frequency at which the impedance is maximum. Bandpass characteristics required of the acoustic wave filter 1 can be obtained through adjustment of the high-low relationship between the resonant frequency and the anti-resonant frequency of each resonator.

By connecting the capacitor 11 in parallel with the series-arm resonator S1, the interval between the resonant frequency and the anti-resonant frequency of the series-arm resonator S1 (hereinafter referred to as the resonance band width) can be reduced, and the resonance Q factor of the resonant circuit including the series-arm resonator S1 and the capacitor 11 connected in parallel can be increased. By connecting the capacitor 21 in parallel with the parallel-arm resonator P1, the resonance band width of the parallel-arm resonator P1 can be reduced, and the resonance Q factor of the resonant circuit including the parallel-arm resonator P1 and the capacitor 21 connected in parallel can be increased. This configuration provides the acoustic wave filter 1 having low loss in the pass band and improved steepness at the boundary between the pass band and the attenuation band.

The acoustic wave filter 1 according to the present example embodiment may include at least one series-arm resonator and at least one parallel-arm resonator, and a bridging capacitance element may be connected to at least one of the series-arm resonator and the parallel-arm resonator.

An acoustic wave device according to the present invention does not have to be an acoustic wave filter including at least one series-arm resonator and at least one parallel-arm resonator, and may be, for example, an acoustic wave resonator device including at least one set including an acoustic wave resonator and a bridging capacitance element connected in parallel.

Next, structures of the acoustic wave resonators (series-arm resonator and parallel-arm resonator) and the capacitance elements included in the acoustic wave filter 1 will be illustrated.

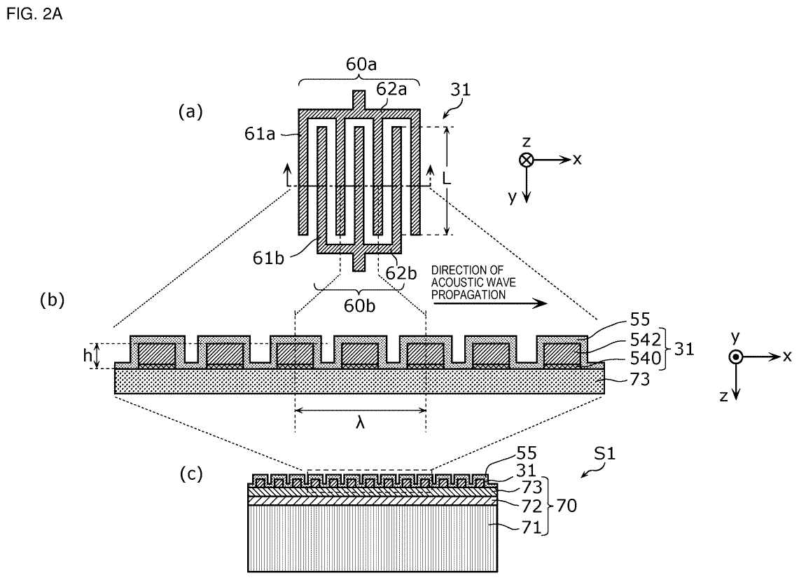

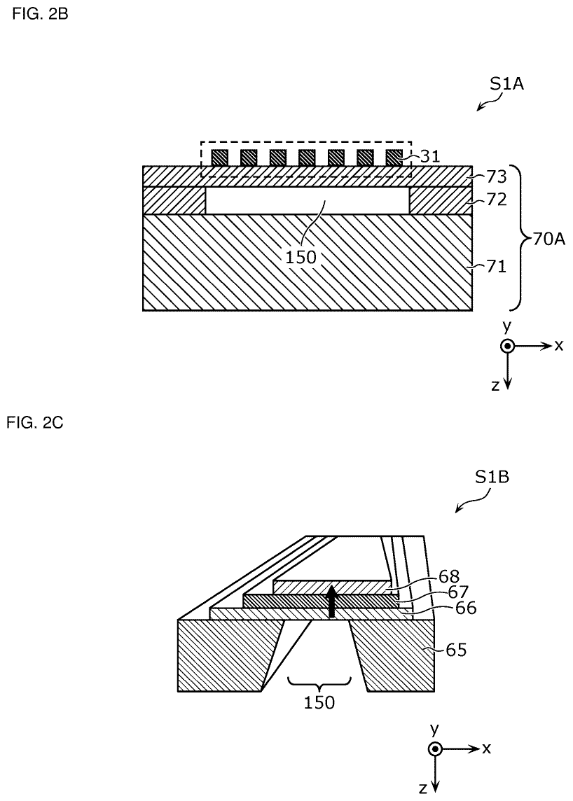

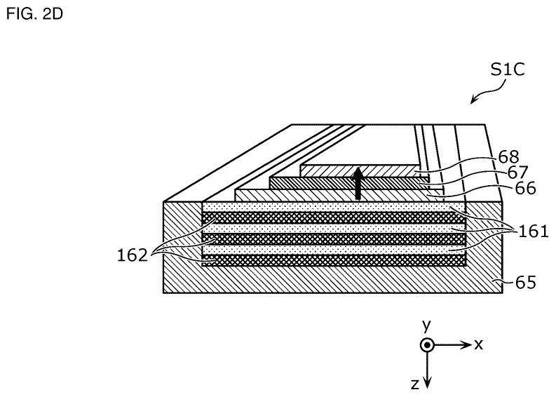

FIG. 2A includes a plan view and a cross-sectional view schematically illustrating a first example of an acoustic wave resonator included in the acoustic wave filter 1 according to the present example embodiment. FIG. 2A illustrates the structure of the series-arm resonator S1 of the acoustic wave resonators included in the acoustic wave filter 1. The series-arm resonator S1 illustrated in FIG. 2A is intended to describe a typical structure of a surface acoustic wave (SAW) resonator included in the acoustic wave filter 1, and parameters such as the number and the lengths of electrode fingers that form an electrode are not limited to the parameters given in this figure. Acoustic wave resonators other than the series-arm resonator S1 that are included in the acoustic wave filter 1 have the structure of the SAW resonator illustrated in FIG. 2A.

As illustrated in part (c) of FIG. 2A, the series-arm resonator S1 includes a piezoelectric substrate 70, an interdigital transducer (IDT) electrode 31, and a protective layer 55.

As illustrated in part (a) of FIG. 2A, the IDT electrode 31 is provided on the piezoelectric substrate 70. The IDT electrode 31 is an example of a functional electrode and includes a pair of comb electrodes 60a and 60b facing each other. The comb electrode 60a includes a plurality of electrode fingers 61a that are parallel to one another and a busbar electrode 62a connecting the plurality of electrode fingers 61a. The comb electrode 60b includes a plurality of electrode fingers 61b parallel to one another and a busbar electrode 62b connecting the plurality of electrode fingers 61b. The electrode fingers 61a and 61b are arranged along a direction perpendicular to the direction of acoustic wave propagation (X-axis direction). The series-arm resonator S1 may include reflectors on both ends of the IDT electrode 31 in the direction of acoustic wave propagation (X-axis direction).

As illustrated in part (b) of FIG. 2A, the IDT electrode 31 has a multilayer structure including an adhesion layer 540 and a main electrode layer 542.

The adhesion layer 540 is a layer to improve the adhesiveness between the piezoelectric substrate 70 and the main electrode layer 542 and is made of, for example, Ti. The main electrode layer 542 is made of, for example, Al including about 1% Cu.

The protective layer 55 covers the IDT electrode 31. The protective layer 55 is a layer intended to protect the main electrode layer 542 from the external environment, adjust temperature characteristics of frequency, and increase moisture resistance, and is, for example, a dielectric film including silicon dioxide as its main component.

Materials used to form the adhesion layer 540, the main electrode layer 542, and the protective layer 55 are not limited to the above-described materials. The IDT electrode 31 need not have the above-described multilayer structure. The IDT electrode 31 may be made of, for example, metal such as Ti, Al, Cu, Pt, Au, Ag, or Pd, or an alloy thereof, or may include a plurality of multilayer bodies each made of the above kind of metal or alloy. The protective layer 55 may be omitted.

Next, a multilayer structure of the piezoelectric substrate 70 will be described.

The piezoelectric substrate 70 is an example of a second substrate and includes a support substrate 71, a low acoustic-velocity layer 72, and a piezoelectric layer 73 as illustrated in part (c) of FIG. 2A, and the piezoelectric substrate 70 has a structure in which the support substrate 71, the low acoustic-velocity layer 72, and the piezoelectric layer 73 are laminated in this order.

The piezoelectric layer 73 is made of, for example, θ° Y-cut X-propagation LiTaO₃ piezoelectric single crystal or piezoelectric ceramic (lithium tantalate single crystal cut along a plane whose normal is an axis rotated θ° from the Y-axis around the X-axis as the center axis or equivalent ceramic, in which a surface acoustic wave propagates in the X-axis direction). The material and the cut angle θ of the piezoelectric single crystal used as the piezoelectric layer 73 are appropriately selected depending on the specifications required of each filter.

The support substrate 71 is a substrate that supports the low acoustic-velocity layer 72, the piezoelectric layer 73, and the IDT electrode 31. Furthermore, the support substrate 71 is a substrate in which the acoustic velocity of a bulk wave in the support substrate 71 is higher than the velocities of acoustic waves such as a surface wave and a boundary wave that propagate through the piezoelectric layer 73, and the support substrate 71 confines surface acoustic waves to the laminated structure of the piezoelectric layer 73 and the low acoustic-velocity layer 72, thus reducing leakage of the surface acoustic waves to the support substrate 71. Examples of materials that can be used for the support substrate 71 include piezoelectric materials such as aluminum nitride, lithium tantalate, lithium niobate, or quartz, ceramics such as alumina, sapphire, magnesia, silicon nitride, silicon carbide, zirconia, cordierite, mullite, steatite, forsterite, spinel, or sialon, dielectric materials such as aluminum oxide, silicon oxynitride, diamond-like carbon (DLC), or diamond, semiconductors such as silicon, and materials including any of the above materials as the main component. The spinel includes, for example, an aluminum compound including oxygen and one or more of Mg, Fe, Zn, or Mn. Examples of such spinel include MgAl₂O₄, FeAl₂O₄, ZnAl₂O₄, or MnAl₂O₄.

The low acoustic-velocity layer 72 is a film in which the acoustic velocity of a bulk wave in the low acoustic-velocity layer 72 is lower than the acoustic velocity of a bulk wave propagating through the piezoelectric layer 73, and is disposed between the piezoelectric layer 73 and the support substrate 71. This structure, along with the property that acoustic waves inherently concentrate energy in a medium with a low acoustic velocity, reduces the leakage of energy of a surface acoustic wave from the piezoelectric layer 73. Examples of materials that can be used for the low acoustic-velocity layer 72 include a dielectric material such as glass, silicon oxide, silicon oxynitride, lithium oxide, tantalum oxide, or a compound of silicon oxide to which fluorine, carbon, or boron is added, and materials including any of the above materials as the main component.

The multilayer structure of the piezoelectric substrate 70 enables the Q factor to significantly increase at the resonant frequency and at the anti-resonant frequency, compared with a structure known in the art in which a piezoelectric substrate including a single layer. That is, since an acoustic wave resonator with a high Q factor can be provided, an acoustic wave filter with low insertion loss can be provided using the acoustic wave resonator.

The support substrate 71 may have a laminated structure including a first support substrate and a high acoustic-velocity film in which the acoustic velocity of a propagating bulk wave is higher than the acoustic velocities of acoustic waves such as a surface wave and a boundary wave propagating through the piezoelectric layer 73. In this case, the high acoustic-velocity film may be made of the same material as the support substrate 71. Examples of material that can be used for the first support substrate include piezoelectric materials such as aluminum nitride, lithium tantalate, lithium niobate, or quartz, ceramics such as alumina, sapphire, magnesia, silicon nitride, silicon carbide, zirconia, cordierite, mullite, steatite, or forsterite, dielectric materials such as diamond or glass, semiconductors such as silicon or gallium nitride, resins, and material including any of the above materials as the main component.

In the present specification, the term “main component of a material” refers to a component that accounts for more than 50% by weight of the material. The main component may be present in any one of single crystal, polycrystalline and amorphous states, or in a mixture of these states.

In the series-arm resonator S1 illustrated in FIG. 2A (c), the piezoelectric substrate 70 may be a piezoelectric single crystal substrate made of, for example, a piezoelectric single crystal of lithium niobate or lithium tantalate.

FIG. 2B is a cross-sectional view schematically illustrating a second example of an acoustic wave resonator included in the acoustic wave filter 1 according to the present example embodiment. FIG. 2B illustrates the structure of a series-arm resonator S1A, which is a variant of the series-arm resonator S1 included in the acoustic wave filter 1. Acoustic wave resonators other than the series-arm resonator S1 that are included in the acoustic wave filter 1 may have the structure of, for example, a laterally excited film bulk acoustic resonator (XBAR) illustrated in FIG. 2B.

As illustrated in FIG. 2B, the series-arm resonator S1A includes a piezoelectric substrate 70A and an IDT electrode 31. The series-arm resonator S1A in this example differs in the configuration of the piezoelectric substrate 70A from the series-arm resonator S1 in the first example. Thus, the following description regarding the series-arm resonator S1A in the second example will focus on the configuration of the piezoelectric substrate 70A, which is different from the piezoelectric substrate 70 of the series-arm resonator S1 in the first example.

The piezoelectric substrate 70A is an example of the second substrate, and includes a support substrate 71, a low acoustic-velocity layer 72, a piezoelectric layer 73, and the IDT electrode 31. The IDT electrode 31 is disposed on the piezoelectric layer 73. The support substrate 71, the low acoustic-velocity layer 72, and the piezoelectric layer 73 are laminated in this order. A gap 150 is provided between the piezoelectric layer 73 and the support substrate 71 in an area overlapping with the IDT electrode 31 in a plan view of the piezoelectric layer 73. The series-arm resonator S1A defines an XBAR.

The piezoelectric layer 73 is made of, for example, a θ° Y-cut X-propagation LiTaO₃ piezoelectric single crystal or piezoelectric ceramic, or a θ°Y-cut X-propagation LiNbO₃ piezoelectric single crystal or piezoelectric ceramic. The material and the cut angle θ of the piezoelectric single crystal used as the piezoelectric layer 73 are appropriately selected depending on the specifications required of each filter.

The support substrate 71 is a substrate that supports the low acoustic-velocity layer 72, the piezoelectric layer 73, and the IDT electrode 31.

The multilayer structure of the piezoelectric substrate 70A enables the Q factor to significantly increase at the resonant frequency and at the anti-resonant frequency, compared with a structure known in the art in which a piezoelectric substrate is made of a single layer. That is, since an acoustic wave resonator with a high Q factor can be provided, an acoustic wave filter with low insertion loss can be provided using the acoustic wave resonator.

FIG. 2C is a cross-sectional view schematically illustrating a third example of an acoustic wave resonator included in the acoustic wave filter 1 according to the present example embodiment. FIG. 2C illustrates the structure of a series-arm resonator S1B, which is a variant of the series-arm resonator S1 included in the acoustic wave filter 1. The series-arm resonator S1B illustrated in FIG. 2C is intended to describe a typical structure of a bulk acoustic wave (BAW) resonator included in the acoustic wave filter 1, and parameters such as the shapes and the thicknesses of a planar electrode 66, a piezoelectric layer 67, a planar electrode 68, and a support substrate 65 are not limited to the parameters provided in the present example. Acoustic wave resonators other than the series-arm resonator S1 that are included in the acoustic wave filter 1 may have the structure of, for example, the BAW resonator illustrated in FIG. 2C.

As illustrated in FIG. 2C, the series-arm resonator S1B includes the planar electrodes 66 and 68 and the piezoelectric layer 67. The planar electrode 66 is an example of a first planar electrode, and the planar electrode 68 is an example of a second planar electrode. The planar electrode 66, the piezoelectric layer 67, and the planar electrode 68 are examples of a functional electrode and are disposed in this order on the support substrate 65 to define a multilayer body. The support substrate 65 is an example of the second substrate and is out of contact with the central region of the planar electrode 66. In FIG. 2C, a gap 150 is provided in the support substrate 65 to provide a non-contact state between the support substrate 65 and the central region of the planar electrode 66. To provide a non-contact state between the support substrate 65 and the central region of the planar electrode 66, a gap may be provided at the interface between the support substrate 65 and the multilayer body instead of a gap in the support substrate 65.

The piezoelectric layer 67 is made of, for example, a piezoelectric single crystal of lithium niobate or lithium tantalate. The piezoelectric layer 67 may also be made of, for example, AlN (aluminum nitride) or ScAlN. The multilayer structure, the material, the cut angle, and the thickness of the piezoelectric layer 67 may be changed as appropriate depending on the property, such as the bandpass characteristics, required of the acoustic wave filter 1.

In the above configuration, when a radio frequency signal is applied between the planar electrode 66 and the planar electrode 68, a potential difference is generated between the two electrodes, and the potential difference distorts the piezoelectric layer 67, generating a bulk acoustic wave in the laminate direction. The film thickness of the piezoelectric layer 67 can be set to a value corresponding to the pass band of the acoustic wave filter 1 to obtain the acoustic wave filter 1 having desired bandpass characteristics.

FIG. 2D is a cross-sectional view schematically illustrating a fourth example of an acoustic wave resonator included in the acoustic wave filter 1 according to the present example embodiment. FIG. 2D illustrates the structure of a series-arm resonator S1C, which is a variant of the series-arm resonator S1 included in the acoustic wave filter 1. The series-arm resonator S1C illustrated in FIG. 2D is intended to describe a typical structure of a solidly mounted resonator (SMR) BAW resonator included in the acoustic wave filter 1, and parameters such as the shapes and the thicknesses of a planar electrode 66, a piezoelectric layer 67, a planar electrode 68, a support substrate 65, and an acoustic multilayer film are not limited to the parameters provided in the present example. Acoustic wave resonators other than the series-arm resonator S1 that are included in the acoustic wave filter 1 may have the structure of the SMR BAW resonator illustrated in FIG. 2D.

As illustrated in FIG. 2D, the series-arm resonator S1C includes the planar electrodes 66 and 68, the piezoelectric layer 67, low acoustic-impedance layers 161, high acoustic-impedance layers 162, and the support substrate 65. The planar electrode 66 is an example of the first planar electrode, and the planar electrode 68 is an example of the second planar electrode. The planar electrode 66, the piezoelectric layer 67, and the planar electrode 68 are examples of a functional electrode and are disposed in this order on the support substrate 65 to define a multilayer body. The support substrate 65 is an example of the second substrate and supports the multilayer body. The acoustic multilayer film has a structure in which the low acoustic-impedance layers 161 and the high acoustic-impedance layers 162 are alternately laminated between the multilayer body and the support substrate 65. This structure enables the series-arm resonator S1C to define an SMR BAW resonator, and Bragg reflection by the acoustic multilayer film confines bulk acoustic waves above the acoustic multilayer film.

In the above configuration, when a radio frequency signal is applied between the planar electrode 66 and the planar electrode 68, a potential difference is generated between the two electrodes, and the potential difference distorts the piezoelectric layer 67, so as to generate a bulk acoustic wave in the laminate direction. The film thickness of the piezoelectric layer 67 can be set to a value corresponding to the pass band of the acoustic wave filter 1 to obtain the acoustic wave filter 1 having desired bandpass characteristics.

In the series-arm resonator S1A illustrated in FIG. 2B, the gap 150 may be replaced with an acoustic multilayer film having a structure in which low acoustic-impedance layers 161 and high acoustic-impedance layers 162 are alternately laminated. As a result, since an energy confinement layer is provided between the piezoelectric layer 73 and the support substrate 71, the series-arm resonator S1A defines and functions as an XBAR.

Next, a structure of the acoustic wave filter according to the present example embodiment will be described in comparison with a structure of an acoustic wave filter 500 according to a comparative example.

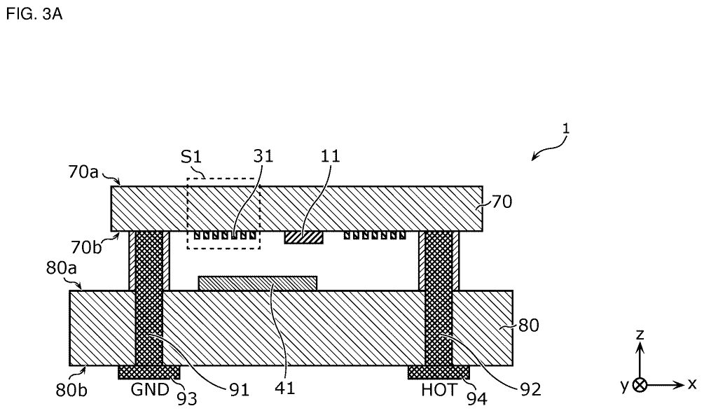

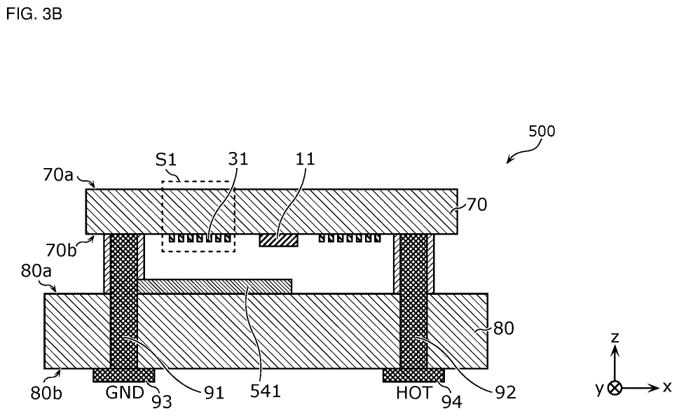

FIG. 3A is a cross-sectional view of the acoustic wave filter 1 according to the present example embodiment. As illustrated in FIG. 3B, the acoustic wave filter 1 includes a mounting board 80, a piezoelectric substrate 70, a series-arm resonator S1, a capacitor 11, a floating planar electrode 41, via conductors 91 and 92, and external connection electrodes 93 and 94.

The mounting board 80 is an example of a first substrate and includes a main surface 80a (first main surface) and a main surface 80b facing away from each other. The mounting board 80 to be used is, for example, a board made of a ceramic body formed by low temperature co-firing (low temperature co-fired ceramics: LTCC) of a multilayer body including a plurality of dielectric layers, a board made of a ceramic body formed by high temperature co-firing (high temperature co-fired ceramics: HTCC), a component-embedded board, a board including a redistribution layer (RDL), or a printed circuit board.

The piezoelectric substrate 70 is an example of the second substrate and includes a main surface 70a and a main surface 70b (second main surface) facing away from each other. The piezoelectric substrate 70 is disposed so that the main surface 70b faces the main surface 80a of the mounting board 80 with a gap interposed therebetween.

The series-arm resonator S1 includes the piezoelectric substrate 70 and an IDT electrode 31 disposed on the main surface 70b. The IDT electrode 31 is an example of a functional electrode.

The capacitor 11 is an example of a bridging capacitance element and is disposed on the main surface 70b. The capacitor 11 includes a pair of comb electrodes that are interdigitated with each other on the main surface 70b.

The series-arm resonator S1 and the capacitor 11 are connected in parallel on the main surface 70b.

The floating planar electrode 41 is an example of a floating electrode and is disposed on the main surface 80a. The floating planar electrode 41 may be, for example, a floating electrode having a shape of a terminal or a bump. A floating electrode is an electrode that is not set at ground potential or a fixed potential. Specifically, an electrode that is not connected to an electrode or a terminal that is set at ground potential or a fixed potential when a radio frequency signal passes through the acoustic wave filter 1. The fixed potential includes the signal potential of a radio frequency signal transmitted through the acoustic wave filter 1.

The via conductor 91 is a conductor provided between the main surface 70b and the main surface 80b and includes a columnar conductor disposed between the main surface 70b and the main surface 80a and a through conductor that extends from the main surface 80a to the main surface 80b. The via conductor 91 is an electrode that is set at the ground potential.

The via conductor 92 is a conductor provided between the main surface 70b and the main surface 80b and includes a columnar conductor disposed between the main surface 70b and the main surface 80a and a through conductor that extends from the main surface 80a to the main surface 80b. The via conductor 92 is an electrode that is set at the signal potential of the radio frequency signal.

The external connection electrode 93 is disposed on the main surface 80b and is connected to the via conductor 91 and to a motherboard on which the acoustic wave filter 1 is mounted. The external connection electrode 93 is an electrode that is set at the ground potential.

The external connection electrode 94 is disposed on the main surface 80b and is connected to the via conductor 92 and to the motherboard on which the acoustic wave filter 1 is mounted. The external connection electrode 94 is an electrode that is set at the signal potential of the radio frequency signal.

A frame may be disposed between the main surface 70b and the main surface 80a so as to surround the acoustic wave resonators, the capacitor 11, and the floating planar electrode 41 in plan view of the main surfaces 70b and 80a. The frame separates the space in which the acoustic wave resonators, the capacitor 11, and the floating planar electrode 41 are disposed from the external space. The frame may be disposed so as to cover the columnar conductors included in the via conductors 91 and 92.

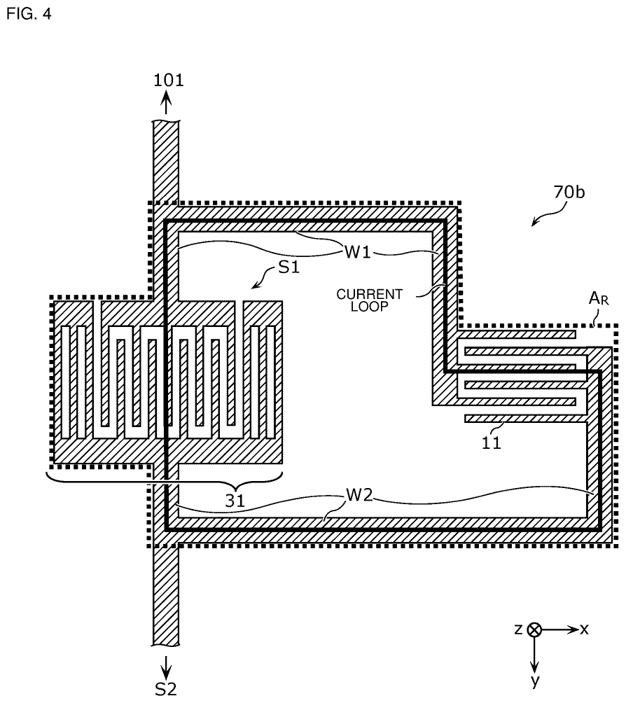

FIG. 4 is a diagram illustrating an electrode layout of the series-arm resonator S1 and the capacitor 11 of the acoustic wave filter 1 according to the present example embodiment. FIG. 4 illustrates the electrode layout on the main surface 70b viewed from the mounting board 80 side. A pair of comb electrodes defining the IDT electrode 31 and a pair of comb electrodes defining the capacitor 11 are disposed on the main surface 70b. One of the comb electrodes included in the IDT electrode 31 and one of the comb electrodes included in the capacitor 11 are connected by a trace W1, and the other of the comb electrodes included in the IDT electrode 31 and the other of the comb electrodes included in the capacitor 11 are connected by a trace W2.

An area A_{R} surrounded by the IDT electrode 31, the capacitor 11, and the traces W1 and W2 connecting the IDT electrode 31 and the capacitor 11, overlaps with at least a portion of the floating planar electrode 41 in plan view of the main surface 80a and the main surface 70b.

The area A_{R} surrounded by the IDT electrode 31, the capacitor 11, and the traces W1 and W2 includes the IDT electrode 31, the capacitor 11, and the traces W1 and W2.

FIG. 3B is a cross-sectional view of the acoustic wave filter 500 according to the comparative example. As illustrated in FIG. 3B, the acoustic wave filter 500 includes a mounting board 80, a piezoelectric substrate 70, a series-arm resonator S1, a capacitor 11, a ground plane electrode 541, via conductors 91 and 92, and external connection electrodes 93 and 94. The acoustic wave filter 500 according to the comparative example differs from the acoustic wave filter 1 according to the present example embodiment only in that the ground plane electrode 541 is provided instead of the floating planar electrode 41. Thus, the following description will focus on the configuration of the ground plane electrode 541 of the acoustic wave filter 500 according to the comparative example.

The ground plane electrode 541 is an example of a ground electrode and is disposed on the main surface 80a and connected to a via conductor 91 set at the ground potential. A ground electrode is an electrode that is set at the ground potential. Specifically, an electrode connected to an electrode or a terminal that is set at the ground potential.

The IDT electrode 31 and the capacitor 11 are disposed on the main surface 70b as in the acoustic wave filter 1 according to the present example embodiment. An area A_{R} surrounded by the IDT electrode 31, the capacitor 11, and traces W1 and W2 connecting the IDT electrode 31 and the capacitor 11, at least partially overlaps with the ground plane electrode 541 in plan view of the main surface 80a and the main surface 70b.

The acoustic wave resonators (series-arm resonators S1 and S2 and parallel-arm resonators P1 and P2) included in the acoustic wave filter 1 exhibit inductive impedance in the frequency range between a resonant frequency and an anti-resonant frequency. In contrast, the capacitor 11 exhibits capacitive impedance. Consequently, the series-arm resonator S1 and the capacitor 11, which are connected in parallel, exhibit approximately opposite phases in the above frequency range, and a current flows between the series-arm resonator S1 and the capacitor 11 due to this phase difference. That is, as illustrated in FIG. 4, the series-arm resonator S1, the capacitor 11, and the traces W1 and W2 define a current loop. This current loop generates a magnetic field (magnetic flux) in the z-axis direction.

When a planar electrode disposed on the main surface 80a so as to overlap with the area A_{R} is not present in plan view of the main surface 80a, the magnetic field (magnetic flux) generated by the current loop leaks into the mounting board 80 and is coupled with conductors such as planar conductors and via conductors provided on the mounting board 80. As a result, parameters, such as circuit constants, of the acoustic wave filter deviate from design values, so as to degrade bandpass characteristics and attenuation characteristics.

In the acoustic wave filter 500 according to the comparative example, the ground plane electrode 541 is disposed on the main surface 80a so as to overlap with the area A_{R} in plan view of the main surface 80a to block the magnetic field generated by the current loop. However, the magnetic field is coupled with the ground plane electrode 541, so as to cause the impedances of the series-arm resonator S1 and the capacitor 11 to change significantly. As a result, parameters, such as circuit constants, of the acoustic wave filter 500 deviate from design values, so as to degrade bandpass characteristics and attenuation characteristics.

In particular, when the acoustic wave filter 500 is downsized and has a lower height, the distance between the main surface 70b and the main surface 80a decreases, and coupling between the magnetic field generated by the current loop and the planar conductors and the via conductors provided on the mounting board 80 increases, so as to further degrade the bandpass characteristics and the attenuation characteristics of the acoustic wave filter 500.

In contrast, in the acoustic wave filter 1 according to the present example embodiment, the floating planar electrode 41 is disposed on the main surface 80a so as to overlap with the area A_{R}. With this configuration, leakage of the magnetic field (magnetic flux) generated by the current loop to the mounting board 80 can be reduced. The floating planar electrode 41 is not set at a fixed potential such as a ground potential, and no definite potential difference is generated between the floating planar electrode 41 and the current loop, thus reducing coupling between the magnetic field and the floating planar electrode 41. Therefore, parameters, such as circuit constants, of the acoustic wave filter 1 do not deviate from design values, thus reducing degradation of bandpass characteristics and attenuation characteristics.

In the acoustic wave filter 1 according to the present example embodiment, the capacitor 11 preferably overlaps at least a portion of the floating planar electrode 41 in plan view of the main surface 70b and the main surface 80a.

With this configuration, coupling of the magnetic field generated by the current loop with the electrodes on the mounting board 80 can be reduced, so as to further improve the attenuation characteristics of the acoustic wave filter 1.

In the acoustic wave filter 1 according to the present example embodiment, the area A_{R} preferably covers the floating planar electrode 41 entirely in the above plan view.

With this configuration, the floating planar electrode 41 can efficiently block the magnetic field generated by the current loop, thus further improving the attenuation characteristics of the acoustic wave filter 1.

In the acoustic wave filter 1 according to the present example embodiment, the area A_{R} including the series-arm resonator S1 and the capacitor 11, overlaps with the floating planar electrode 41 in the above plan view. Instead of (or in addition to) the above configuration, the acoustic wave filter according to example embodiments of the present invention may have a configuration in which the area including the parallel-arm resonator P1 and the capacitor 21 overlaps, with the floating electrode in the above plan view. With this configuration, degradation of bandpass characteristics and attenuation characteristics of the acoustic wave filter can be reduced.

An example embodiment of the present invention also includes an acoustic wave device (acoustic wave resonator device) including either the combination of the series-arm resonator S1 and the capacitor 11 or the combination of the parallel-arm resonator P1 and the capacitor 21 in the acoustic wave filter 1. With this configuration, degradation of bandpass characteristics and attenuation characteristics of the acoustic wave resonator device can be reduced.

Next, description will be provided with regard to a circuit configuration of a multiplexer 100 according to an example embodiment of the present invention including an acoustic wave filter according to an example embodiment of the present invention.

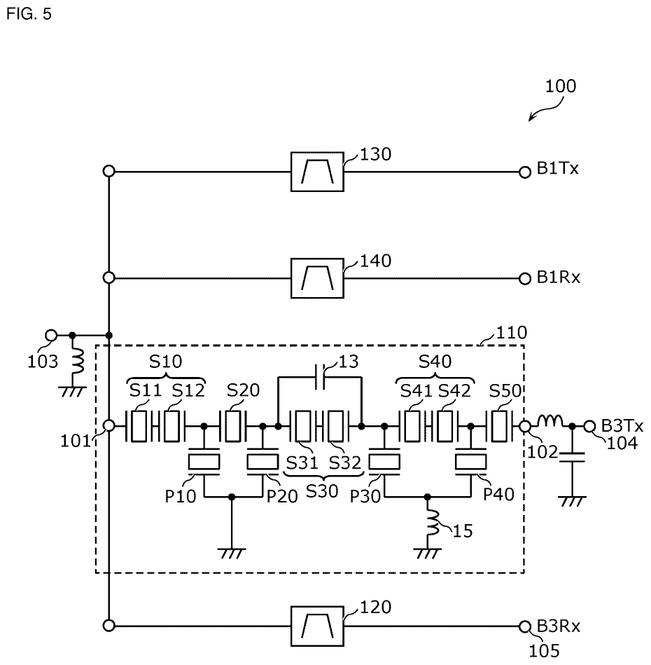

FIG. 5 is a circuit diagram of a multiplexer 100 according to the present example embodiment. As illustrated in FIG. 5, the multiplexer 100 includes a common terminal 103, an acoustic wave filter 110, and filters 120, 130, and 140.

The acoustic wave filter 110 includes series-arm resonators S10, S20, S30, S40, and S50, parallel-arm resonators P10, P20, P30, and P40, a capacitor 13, an inductor 15, and input/output terminals 101 and 102. The acoustic wave filter 110 is, for example, a band pass filter having a pass band that covers a transmit band in Band A.

The input/output terminal 101 is connected to the common terminal 103.

Each of the series-arm resonators S10 to S50 includes an acoustic wave resonator and is disposed in series in a series-arm path connecting the input/output terminal 101 (first input/output terminal) and the input/output terminal 102 (second input/output terminal). The series-arm resonator S10 includes split resonators S11 and S12 connected in series. The series-arm resonator S30 includes split resonators S31 and S32 connected in series. The series-arm resonator S40 includes split resonators S41 and S42 connected in series. Each of the parallel-arm resonators P10 to P40 includes an acoustic wave resonator and is connected between the series-arm path and ground.

Each of the series-arm resonators S10 to S50 and the parallel-arm resonators P10 to P40 may include a single acoustic wave resonator or may include split resonators.

The capacitor 13 is an example of a bridging capacitance element and is connected in parallel with the series-arm resonator S30.

Since the capacitor 13 is connected in parallel with the series-arm resonator S30, the resonance band width of the series-arm resonator S30 can be reduced, and the resonance Q factor of the resonant circuit in which the series-arm resonator S30 and the capacitor 13 are connected in parallel can be increased. This configuration provides the acoustic wave filter 110 having low loss within the pass band and improved steepness at the boundary between the pass band and the attenuation band.

The inductor 15 is connected between ground and the parallel-arm resonators P30 and P40. Through adjustment of the inductance value of the inductor 15, an attenuation pole can be provided in a predetermined frequency range or attenuation can be improved, in the bandpass characteristics of the acoustic wave filter 110.

The acoustic wave filter 110 may include at least one series-arm resonator and at least one parallel-arm resonator, and a bridging capacitance element may be connected to at least one of the at least one series-arm resonator and the at least one parallel-arm resonator.

The filter 120 is an example of a first filter and is, for example, a band pass filter having a pass band that includes a receive band in Band A. The filter 120 is connected between the common terminal 103 and a signal output terminal 105. The filter 130 is, for example, a band pass filter having a pass band that includes a transmit band in Band B and is connected to the common terminal 103. The filter 140 is, for example, a band pass filter having a pass band that includes a receive band in Band B and is connected to the common terminal 103.

Band A is, for example, Band B3 for 4G-LTE or Band n3 for 5G-NR. Band B is, for example, Band B1 for 4G-LTE or Band n1 for 5G-NR. The multiplexer 100 to which the above band combination is applied defines a quadplexer.

Each of the acoustic wave resonators (the series-arm resonators S10 to S50 and the parallel-arm resonators P10 to P40) included in the acoustic wave filter 110 may have any of the following structures: a SAW resonator illustrated in FIG. 2A, an XBAR illustrated in FIG. 2B, a BAW resonator illustrated in FIG. 2C, and an SMR-type BAW resonator illustrated in FIG. 2D.

Next, a structure of the multiplexer 100 according to the present example embodiment will be described.

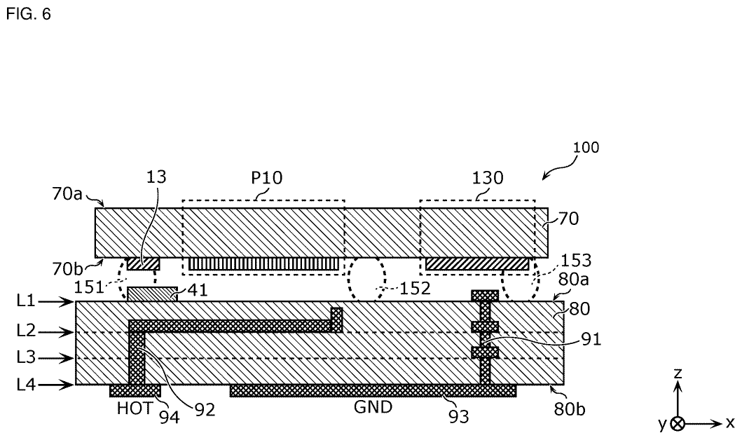

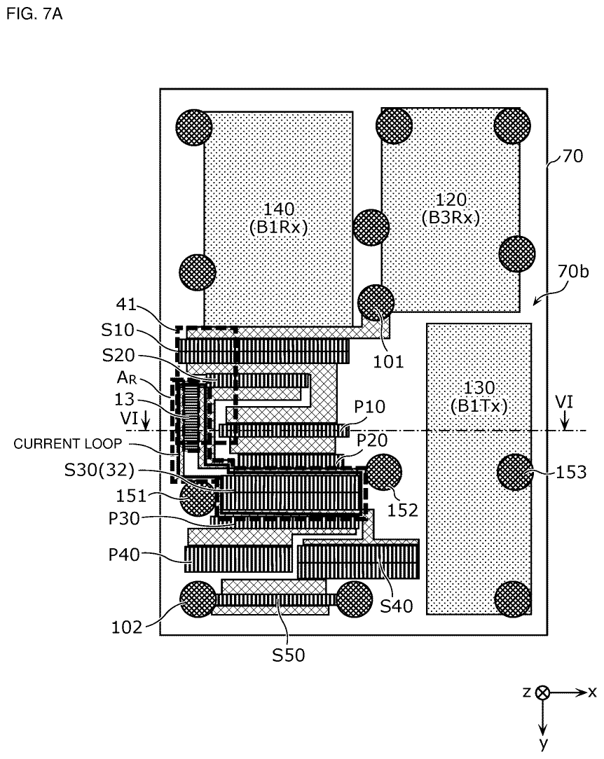

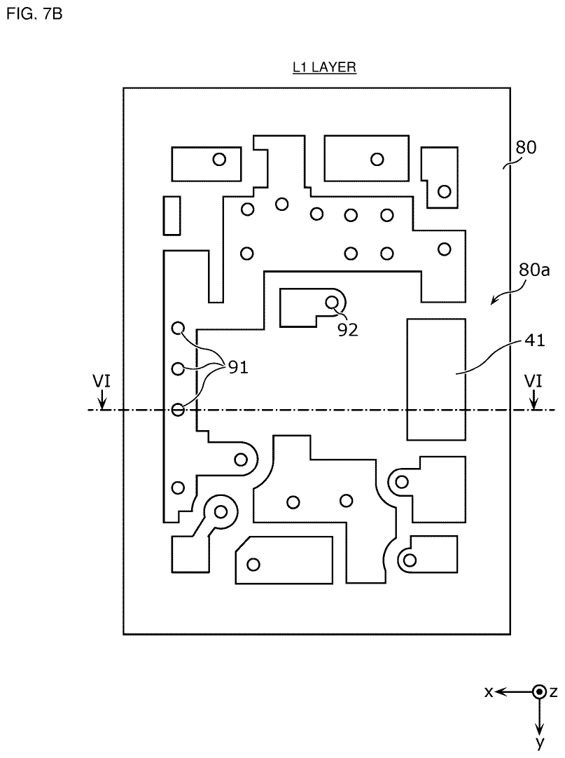

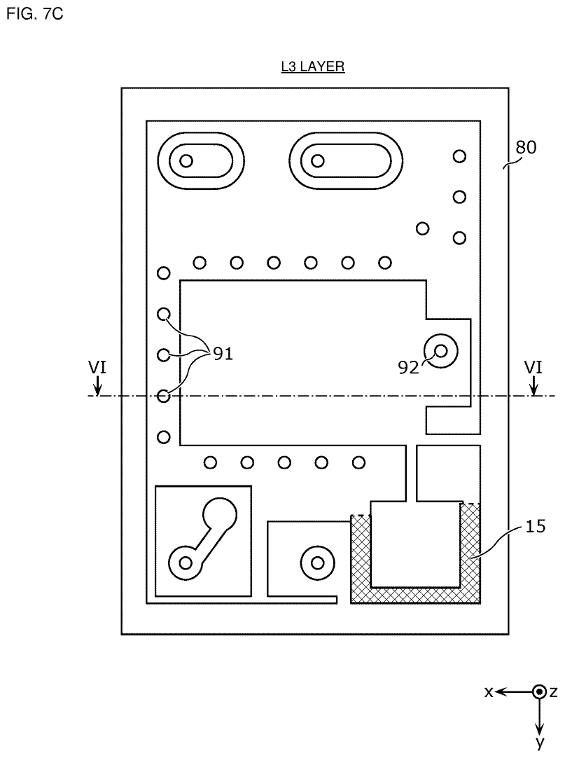

FIG. 6 is a cross-sectional view of the multiplexer 100 according to the present example embodiment. FIG. 7A is a first plan view illustrating an electrode layout of the multiplexer 100 according to the present example embodiment. FIG. 7B is a second plan view illustrating an electrode layout of the multiplexer 100 according to the present example embodiment. FIG. 7C is a third plan view illustrating an electrode layout of the multiplexer 100 according to the present example embodiment. FIG. 7A illustrates the electrode layout (first plan view) on the main surface 70b of the piezoelectric substrate 70, FIG. 7B illustrates the electrode layout (second plan view) on the L1 layer (main surface 80a) of the mounting board 80, and FIG. 7C illustrates the electrode layout (third plan view) on the L3 layer of the mounting board 80. FIG. 6 is a cross-sectional view taken along line VI-VI in FIGS. 7A to 7C, viewed from the positive side of the y-axis. The electrode layouts on the L2 layer and L4 layer of the mounting board 80 are not illustrated.

As illustrated in FIG. 6 to FIG. 7C, the multiplexer 100 includes the mounting board 80, the piezoelectric substrate 70, the acoustic wave filter 110, the filters 120 to 140, a floating planar electrode 41, via conductors 91 and 92, and external connection electrodes 93 and 94.

The mounting board 80 is an example of the first substrate, and as illustrated in FIG. 6, includes the main surface 80a (first main surface) and a main surface 80b facing away from each other. The L1 layer, the L2 layer, the L3 layer, and the L4 layer on which planar conductors are provided are provided from the main surface 80a to the main surface 80b in the mounting board 80. The L1 layer includes the main surface 80a, and the L4 layer includes the main surface 80b. The mounting board 80 to be used is, for example, an LTCC board, an HTCC board, a component-embedded board, a board having an RDL, or a printed circuit board.

The piezoelectric substrate 70 is an example of the second substrate, and as illustrated in FIG. 6, includes a main surface 70a and a main surface 70b (second main surface) facing away from each other. The piezoelectric substrate 70 is disposed so that the main surface 70b faces the main surface 80a of the mounting board 80 with a gap interposed therebetween.

The acoustic wave filter 110 includes the series-arm resonators S10 to S50, the parallel-arm resonators P10 to P40, the capacitor 13, the inductor 15, and the input/output terminals 101 and 102.

As illustrated in FIG. 7A, the series-arm resonators S10 to S50 and the parallel-arm resonators P10 to P40 (IDT electrodes of these resonators) are provided on the main surface 70b. The electrodes of the filters 120 to 140 are also provided on the main surface 70b. Bump electrodes to join the piezoelectric substrate 70 and the mounting board 80 are also disposed on the main surface 70b.

The series-arm resonator S30 includes the piezoelectric substrate 70 and an IDT electrode 32 disposed on the main surface 70b. The IDT electrode 32 is an example of a functional electrode.

The capacitor 13 is an example of a bridging capacitance element and is disposed on the main surface 70b. The capacitor 13 includes a pair of comb electrodes that are interdigitated with each other on the main surface 70b.

The series-arm resonator S30 and the capacitor 13 are connected in parallel on the main surface 70b.

The floating planar electrode 41 is an example of a floating electrode and is disposed on the main surface 80a as illustrated in FIG. 7B. The floating planar electrode 41 may be a floating electrode having a shape of a terminal or a bump, for example.

As illustrated in FIG. 7C, the inductor 15 includes a coil conductor provided on the L3 layer in the mounting board 80.

The via conductor 91 is a conductor provided between the main surface 80a and the main surface 80b and is an electrode that is set at ground potential. The via conductor 92 is a conductor provided between the main surface 80a and the main surface 80b and is an electrode that is set at the signal potential of a radio frequency signal.

The external connection electrode 93 is disposed on the main surface 80b and is connected to the via conductor 91 and to a motherboard on which the multiplexer 100 is mounted. The external connection electrode 93 is an electrode that is set at the ground potential. The external connection electrode 94 is disposed on the main surface 80b and is connected to the via conductor 92 and to the motherboard on which the multiplexer 100 is mounted. The external connection electrode 94 is an electrode that is set at the signal potential of the radio frequency signal.

The mounting board 80 and the piezoelectric substrate 70 are joined using a plurality of bump electrodes including bump electrodes 151, 152, and 153, and a gap is interposed between the main surface 80a and the main surface 70b.

A frame may be disposed between the main surface 70b and the main surface 80a so as to surround the acoustic wave resonators, the capacitor 13, and the floating planar electrode 41. The frame separates the space in which the acoustic wave resonators, the capacitor 13, and the floating planar electrode 41 are disposed from the external space.

An area A_{R} surrounded by the IDT electrode 32, the capacitor 13, and a trace connecting the IDT electrode 32 and the capacitor 13, overlaps with at least a portion of the floating planar electrode 41 in plan view of the main surface 80a and the main surface 70b.

The area A_{R} surrounded by the IDT electrode 32, the capacitor 13, and the trace connecting the IDT electrode 32 and the capacitor 13 includes the IDT electrode 32, the capacitor 13, and the trace.

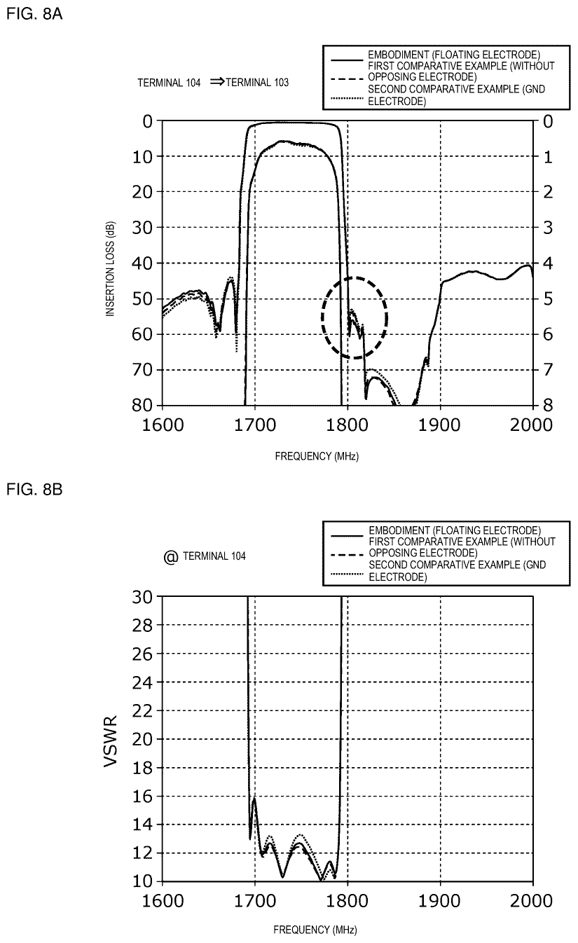

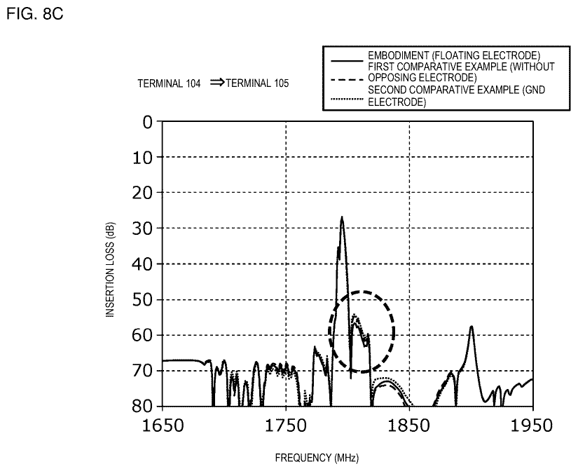

FIG. 8A is a graph illustrating bandpass characteristics of acoustic wave filters 110 included in multiplexers according to the present example embodiment, a first comparative example, and a second comparative example. FIG. 8B is a graph illustrating voltage standing wave ratios of the acoustic wave filters 110 included in the multiplexers according to the present example embodiment, the first comparative example, and the second comparative example. FIG. 8C is a graph illustrating isolation characteristics of the multiplexers according to the present example embodiment, the first comparative example, and the second comparative example.

The multiplexer according to the first comparative example differs in configuration from the multiplexer 100 according to the present example embodiment only in that the floating planar electrode 41 is not disposed on the main surface 80a. The multiplexer according to the second comparative example differs in configuration from the multiplexer 100 according to the present example embodiment only in that a ground plane electrode is disposed on the main surface 80a instead of the floating planar electrode 41.

The acoustic wave resonators (the series-arm resonators S10 to S50 and the parallel-arm resonators P10 to P40) included in the acoustic wave filter 110 exhibit an inductive impedance in the frequency range between a resonant frequency and an anti-resonant frequency. In contrast, the capacitor 13 exhibits a capacitive impedance. Consequently, the series-arm resonator S30 and the capacitor 13, which are connected in parallel, exhibit approximately opposite phases in the above frequency range, and a current flows between the series-arm resonator S30 and the capacitor 13 due to this phase difference. The series-arm resonator S30, the capacitor 13, and the trace connecting the series-arm resonator S30 and the capacitor 13 define a current loop. This current loop generates a magnetic field (magnetic flux) in the z-axis direction.

Since a planar electrode disposed on the main surface 80a so as to overlap with the area A_{R} is not present in plan view of the main surface 80a in the multiplexer according to the first comparative example, the magnetic field (magnetic flux) generated by the current loop defined by the IDT electrode 32, the capacitor 13, and the trace leaks into the mounting board 80, and, for example, is coupled with the magnetic field generated by the inductor 15 provided on the L3 layer. As a result, as illustrated in FIG. 8A, attenuation in the vicinity of frequencies higher than the pass band is reduced (as enclosed by a dashed circle in FIG. 8A). Furthermore, as illustrated in FIG. 8C, due to the reduction in the attenuation of the acoustic wave filter 110, the isolation between the acoustic wave filter 110 and the filter 120 is degraded (as enclosed by a dashed circle in FIG. 8C).

In a multiplexer according to the second comparative example, a ground plane electrode is disposed on the main surface 80a so as to overlap with the area A_{R} in plan view of the main surface 80a to block a magnetic field (magnetic flux) generated by the current loop. As a result, the magnetic field is coupled with the ground plane electrode, causing the impedances of the series-arm resonator S30 and the capacitor 13 to change significantly. This change degrades a voltage standing wave ratio within the pass band of the acoustic wave filter 110 at the signal input terminal 104, as illustrated in FIG. 8B. The changes in the impedances also reduce attenuation in the vicinity of frequencies higher than the pass band, as illustrated in FIG. 8A. The reduction in the attenuation of the acoustic wave filter 110 degrades the isolation between the acoustic wave filter 110 and the filter 120, as illustrated in FIG. 8C.

In contrast to the first and second comparative examples, the floating planar electrode 41 is disposed on the main surface 80a so as to overlap with the area A_{R} in the multiplexer 100 according to the present example embodiment. With this configuration, leakage of the magnetic field (magnetic flux) generated by the current loop to the mounting board 80 can be reduced. The floating planar electrode 41 is not set at a fixed potential such as ground potential, and no definite potential difference is generated between the floating planar electrode 41 and the current loop, thus reducing coupling between the magnetic field and the floating planar electrode 41. Therefore, parameters, such as circuit constants, of the acoustic wave filter 110 and the multiplexer 100 do not deviate from design values. As a result, as illustrated in FIG. 8A, a large amount of attenuation can be obtained in the vicinity of frequencies higher than the pass band of the acoustic wave filter 110 (as enclosed by the dashed circle in FIG. 8A). As illustrated in FIG. 8B, the voltage standing wave ratio within the pass band of the acoustic wave filter 110 is not degraded. Furthermore, as illustrated in FIG. 8C, the isolation between the acoustic wave filter 110 and the filter 120 can be improved (as enclosed by the dashed circle in FIG. 8C).

In the multiplexer 100 according to the present example embodiment, the capacitor 13 preferably overlaps with at least a portion of the floating planar electrode 41 in plan view of the main surface 70b and the main surface 80a.

With this configuration, coupling of both a magnetic field generated by the current loop and an electric field generated by the capacitor 13 with the electrodes on the mounting board 80 can be reduced, so as to further improve the attenuation characteristics of the acoustic wave filter 1 and the isolation characteristics of the multiplexer 100.

In the multiplexer 100 according to the present example embodiment, the area A_{R} preferably covers the floating planar electrode 41 entirely in the above plan view.

With this configuration, the floating planar electrode 41 can efficiently block the magnetic field generated by the current loop, further improving the attenuation characteristics of the acoustic wave filter 1 and the isolation characteristics of the multiplexer 100.

As described above, an acoustic wave device according an example embodiment of the present invention includes a first substrate including a first main surface, a second substrate including a second main surface facing the first main surface with a gap interposed therebetween, an acoustic wave resonator including a functional electrode and located in or on the second substrate, a bridging capacitance element on the second main surface and connected in parallel with the acoustic wave resonator, and a floating electrode on the first main surface. An area surrounded by the functional electrode, the bridging capacitance element, and a trace connecting the functional electrode and the bridging capacitance element, overlaps with at least a portion of the floating electrode in plan view of the first main surface and the second main surface.

With this configuration, leakage of a magnetic field generated by a current loop defined by the functional electrode and the bridging capacitance element to the first substrate can be reduced. The floating electrode is not set at a fixed potential such as ground potential, and no definite potential difference is generated between the floating electrode and the current loop, thus reducing coupling between the magnetic field and the floating electrode. Therefore, parameters, such as circuit constants, of the acoustic wave device do not deviate from design values, thus reducing degradation of attenuation characteristics.

For example, in an acoustic wave device according to an example embodiment of the present invention, the bridging capacitance element overlaps with at least a portion of the floating electrode in the above plan view.

With this configuration, coupling of both a magnetic field generated by the current loop and an electric field generated by the bridging capacitance element with the electrodes on the first substrate can be reduced, thus further improving the attenuation characteristics of the acoustic wave device.

For example, in an acoustic wave device according to an example embodiment of the present invention, the above area covers the floating electrode entirely in the above plan view.

With this configuration, the floating electrode can efficiently block the magnetic field generated by the current loop, thus further improving the attenuation characteristics of the acoustic wave device.

For example, in an acoustic wave device according to an example embodiment of the present invention, the bridging capacitance element includes a pair of comb electrodes.

With this configuration, the bridging capacitance element can be downsized, thus reducing the area of the second main surface.

For example, an acoustic wave filter 1 according to an example embodiment of the present invention includes a mounting board 80 including a main surface 80a, a piezoelectric substrate 70 including a main surface 70b facing the main surface 80a with a gap interposed therebetween, a series-arm resonator S1 including a functional electrode and located on the piezoelectric substrate 70, a capacitor 11 on the main surface 70b and connected in parallel with the series-arm resonator S1, and a floating planar electrode 41 on the main surface 80a. The piezoelectric substrate 70 includes a piezoelectric layer 73 on the main surface 70b side, the functional electrode includes an IDT electrode 31 on the piezoelectric layer 73, and an area A_{R} surrounded by the IDT electrode 31, the capacitor 11, and traces W1 and W2, overlaps with at least a portion of the floating planar electrode 41 in plan view of the main surface 80a and the main surface 70b.

With this configuration, leakage of a magnetic field generated by a current loop defined by the IDT electrode 31 and the capacitor 11 to the mounting board 80 can be reduced. The floating planar electrode 41 is not set at a fixed potential such as ground potential, and no definite potential difference is generated between the floating planar electrode 41 and the current loop, thus reducing coupling between the magnetic field and the floating planar electrode 41. Therefore, parameters, such as circuit constants, of the acoustic wave filter 1 do not deviate from design values, thus reducing degradation of attenuation characteristics.

For example, in an acoustic wave device according to an example embodiment of the present invention, the functional electrode includes planar electrodes 66 and 68 with a piezoelectric layer 67 interposed therebetween, and the planar electrode 66, the piezoelectric layer 67, and the planar electrode 68 are provided on the second main surface in this order from the second main surface toward the first main surface.

With this configuration in which the acoustic wave resonator is a BAW resonator, leakage of a magnetic field generated by a current loop defined by the functional electrode and the bridging capacitance element to the first substrate can be reduced. The floating electrode is not set at a fixed potential such as ground potential, and no definite potential difference is generated between the floating electrode and the current loop, thus reducing coupling between the magnetic field and the floating electrode. Therefore, parameters, such as circuit constants, of the acoustic wave device do not deviate from design values, thus reducing degradation of attenuation characteristics.

An acoustic wave filter 110 according to an example embodiment of the present invention includes a mounting board 80 including a main surface 80a, a piezoelectric substrate 70 including a main surface 70b facing the main surface 80a with a gap interposed therebetween, series-arm resonators S10 to S50 in a series-arm path connecting input/output terminals 101 and 102, parallel-arm resonators P10 to P40 connected between the series-arm path and ground, a capacitor 13 on the main surface 70b and connected in parallel with the series-arm resonator S30, and a floating planar electrode 41 on the main surface 80a. The series-arm resonator S30 is an acoustic wave resonator including an IDT electrode 32. An area A_{R} surrounded by the IDT electrode 32, the capacitor 13, and a trace connecting the IDT electrode 32 and the capacitor 13, overlaps with at least a portion of the floating planar electrode 41 in plan view of the main surface 80a and the main surface 70b.

With this configuration, leakage of a magnetic field generated by a current loop defined by the IDT electrode 32 and the capacitor 13 to the mounting board 80 can be reduced. The floating planar electrode 41 is not set at a fixed potential such as ground potential, and no definite potential difference is generated between the floating planar electrode 41 and the current loop, thus reducing coupling between the magnetic field and the floating planar electrode 41. Therefore, parameters, such as circuit constants, of the acoustic wave filter 110 do not deviate from design values, thus reducing degradation of attenuation characteristics.

For example, an acoustic wave filter 110 according to an example embodiment of the present invention further includes an inductor 15 connected between the parallel-arm resonator P30 and ground, the mounting board 80 is made of an insulating body, and the inductor 15 includes a coil conductor provided in or on the insulating body.

With this configuration of the floating planar electrode 41, coupling of a magnetic field generated by the current loop with the inductor 15 provided on the mounting board 80 can be reduced. Thus, degradation of attenuation characteristics of the acoustic wave filter 110 can be reduced.

A multiplexer 100 according to an example embodiment of the present invention includes a common terminal 103, the acoustic wave filter 110 connected to the common terminal 103, and a filter 120 connected to the common terminal 103.

With this configuration, leakage of a magnetic field generated by the current loop to the mounting board 80 can be reduced. Since no definite potential difference is generated between the floating planar electrode 41 and the current loop, coupling between the magnetic field and the floating planar electrode 41 is reduced. Thus, parameters, such as circuit constants, of the acoustic wave filter 110 and the multiplexer 100 do not deviate from design values. Therefore, attenuation characteristics of the acoustic wave filter 110 and isolation characteristics of the multiplexer 100 can be improved.

Although acoustic wave devices, acoustic wave filters, and multiplexers have been described above based on example embodiments, the acoustic wave devices, the acoustic wave filters, and the multiplexers according to the present invention are not limited to those in the above example embodiments. The present invention also includes other example embodiments provided through combinations of any of the elements in the above example embodiments, modifications made to the example embodiments through various alterations that those skilled in the art conceive without departing from the scope and spirit of the present invention, and various apparatuses including the acoustic wave devices, the acoustic wave filters, and the multiplexers according to the example embodiments of the present invention.

Example embodiments of the present invention can widely be used in, for example, communication apparatuses, such as mobile phones, as an acoustic wave filter and a multiplexer with low loss and high attenuation that can be applied to multiband frequency standards.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first substrate including a first main surface;
a second substrate including a second main surface facing the first main surface with a gap interposed therebetween;
an acoustic wave resonator including a functional electrode and located in or on the second substrate;
a bridging capacitance element on the second main surface and connected in parallel with the acoustic wave resonator; and
a floating electrode on the first main surface; wherein
an area surrounded by the functional electrode, the bridging capacitance element, and a trace connecting the functional electrode and the bridging capacitance element, overlaps with at least a portion of the floating electrode in plan view of the first main surface and the second main surface.

2. The acoustic wave device according to claim 1, wherein the bridging capacitance element overlaps with at least a portion of the floating electrode in the plan view.

3. The acoustic wave device according to claim 1, wherein the area covers the floating electrode entirely in the plan view.

4. The acoustic wave device according to claim 1, wherein the bridging capacitance element includes a pair of comb electrodes.

5. The acoustic wave device according to claim 1, wherein
the second substrate includes a piezoelectric layer on the second main surface side; and
the functional electrode includes an interdigital transducer (IDT) electrode on the piezoelectric layer.

6. The acoustic wave device according to claim 1, wherein
the functional electrode includes a first planar electrode and a second planar electrode with a piezoelectric layer interposed therebetween; and
the first planar electrode, the piezoelectric layer, and the second planar electrode are provided on the second main surface in this order from the second main surface toward the first main surface.

7. The acoustic wave device according to claim 5, wherein the functional electrode further includes a protective layer covering the IDT electrode.

8. The acoustic wave device according to claim 5, wherein the IDT electrode includes Ti, Al, Cu, Pt, Au, Ag, or Pd, or an alloy including at least one of Ti, Al, Cu, Pt, Au, Ag, or Pd.

9. An acoustic wave filter comprising:
a first substrate including a first main surface;
a second substrate including a second main surface facing the first main surface with a gap interposed therebetween;
a series-arm resonator in a series-arm path connecting a first input/output terminal and a second input/output terminal;
a parallel-arm resonator connected between the series-arm path and ground;
a bridging capacitance element on the second main surface and connected in parallel with one of the series-arm resonator and the parallel-arm resonator; and
a floating electrode on the first main surface; wherein
the one of the series-arm resonator and the parallel-arm resonator includes an acoustic wave resonator including a functional electrode; and
an area surrounded by the functional electrode, the bridging capacitance element, and a trace connecting the functional electrode and the bridging capacitance element, overlaps with at least a portion of the floating electrode in plan view of the first main surface and the second main surface.

10. The acoustic wave filter according to claim 9, further comprising:
an inductor connected between the parallel-arm resonator and ground; wherein
the first substrate includes an insulating body; and
the inductor includes a coil conductor provided in or on the insulating body.

11. A multiplexer comprising:
a common terminal;
the acoustic wave filter according to claim 9 connected to the common terminal; and
a first filter connected to the common terminal.

12. The multiplexer according to claim 11, further comprising:
an inductor connected between the parallel-arm resonator and ground; wherein
the first substrate includes an insulating body; and
the inductor includes a coil conductor provided in or on the insulating body.

13. A multiplexer comprising:
a common terminal;
the acoustic wave device according to claim 1 connected to the common terminal; and
a first filter connected to the common terminal.

14. The multiplexer according to claim 13, wherein the bridging capacitance element overlaps with at least a portion of the floating electrode in the plan view.

15. The multiplexer according to claim 13, wherein the area covers the floating electrode entirely in the plan view.

16. The multiplexer according to claim 13, wherein the bridging capacitance element includes a pair of comb electrodes.

17. The multiplexer according to claim 13, wherein
the second substrate includes a piezoelectric layer on the second main surface side; and
the functional electrode includes an interdigital transducer (IDT) electrode on the piezoelectric layer.

18. The multiplexer according to claim 13, wherein
the functional electrode includes a first planar electrode and a second planar electrode with a piezoelectric layer interposed therebetween; and
the first planar electrode, the piezoelectric layer, and the second planar electrode are provided on the second main surface in this order from the second main surface toward the first main surface.

19. The multiplexer according to claim 17, wherein the functional electrode further includes a protective layer covering the IDT electrode.

20. The multiplexer according to claim 17, wherein the IDT electrode includes Ti, Al, Cu, Pt, Au, Ag, or Pd, or an alloy including at least one of Ti, Al, Cu, Pt, Au, Ag, or Pd.
